(19) United States
(12) Patent Application Publication
(10) Pub. No.: US 2008/0099231 A1
(43) Pub. Date: May 1, 2008

(54) PRINTED CIRCUIT BOARD ABLE TO SUPPRESS SIMULTANEOUS SWITCHING NOISE

(75) Inventors: LIANG-YAO CHANG, Taipei Hsien (TW); SHOU-KUO HSU, Taipei Hsien (TW)

Correspondence Address: PCE INDUSTRY, INC.;ATT. CHENG-JU CHIANG J, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/829,974

(22) Filed: Jul. 30, 2007

(30) Foreign Application Priority Data
Oct. 25, 2006 (CN) 200610063288.2

(51) Int. Cl. H05K 1/03; H05K 1/11

(52) U.S. Cl. 174/256; 174/261

(57) ABSTRACT

An exemplary printed circuit board includes a power plane, and a ground plane. The power plane includes two power modules, and a strip made of insulating medium disposed between the two power modules for insulating the two power modules from each other. The ground plane is insulated from the power plane, a plurality of vias electrically connects the power plane and the ground plane, and is close to the strip. Each via is insulated from the power module by an annular insulating medium. Each power module and the vias forms an equivalent coupling capacitance, and SSN can be conducted to the ground plane via the equivalent coupling capacitance, therefore, the SSN in the PCB is suppressed.

### BACKGROUND OF THE INVENTION

1. Field of the Invention

The present invention relates to printed circuit boards, and particularly to suppression of simultaneous switching noise (SSN) in a printed circuit board (PCB).

2. Description of Related Art

As the density of integrated circuits on PCBs increases, the problems associated with signal switching noise become greater. Many integrated circuits have a large number of input/output (I/O) drivers. Several hundred drivers may be present in integrated circuits, and this number will undoubtedly become greater as packaging density increases in the future. Noise that occurs in the PCB when a large number of drivers simultaneously switch from one state to another is known as SSN. The problem may be even more acute when the drivers all switch in the same direction (e.g. high to low). When a large number of drivers switch simultaneously, various signal integrity problems may occur. For example, a conventional PCB as shown in FIG. 3 includes a ground plane 100, a power plane 200 insulated from the ground plane 100 by a fiberglass material, and two integrated circuits A, B positioned on a surface plane (not shown) of the PCB. The power plane 200 includes two power modules 210, 220 insulated from each other by an insulating medium 230 made up of fiberglass material to respectively provide power supply for the integrated circuits A, B. When drivers in the integrated circuit A simultaneously switch from one state to another, SSN from the integrated circuit A can be transmitted to the power module 220 via the power module 210 and an equivalent coupling capacitance formed by the power modules 210, 220 and the insulating medium 230. Then the integrated circuit B may receive the SSN and cause incorrect actions.

What is needed, therefore, is a PCB with suppressed SSN therein.

### SUMMARY OF THE INVENTION

An exemplary printed circuit board includes a power plane, and a ground plane. The power plane includes two power modules, and a strip made of insulating medium disposed between the two power modules for insulating the two power modules from each other. The ground plane is insulated from the power plane, a plurality of vias electrically connects the power plane and the ground plane, and is close to the strip. Each via is insulated from the power module by an annular insulating medium.

Other advantages and novel features will become more apparent from the following detailed description when taken in conjunction with the accompanying drawings, in which:

### BRIEF DESCRIPTION OF THE DRAWINGS

FIG. 1 is an isometric, schematic diagram of a printed circuit board in accordance with a preferred embodiment of the present invention;

FIG. 2 is a top plan view of FIG. 1;

FIG. 3 is a schematic diagram of a conventional printed circuit board; and

FIG. 4 is a graph of insertion loss versus frequency in the PCBs of FIGS. 1 and 3.

### DETAILED DESCRIPTION OF THE INVENTION

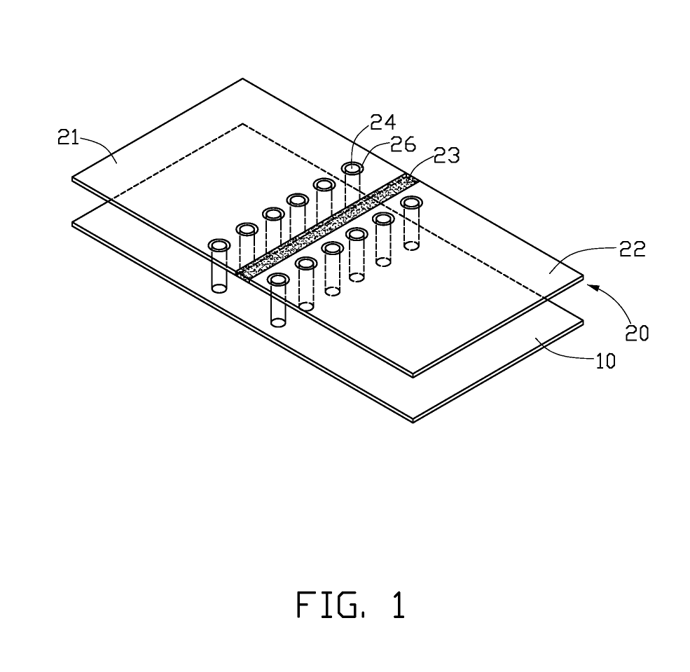

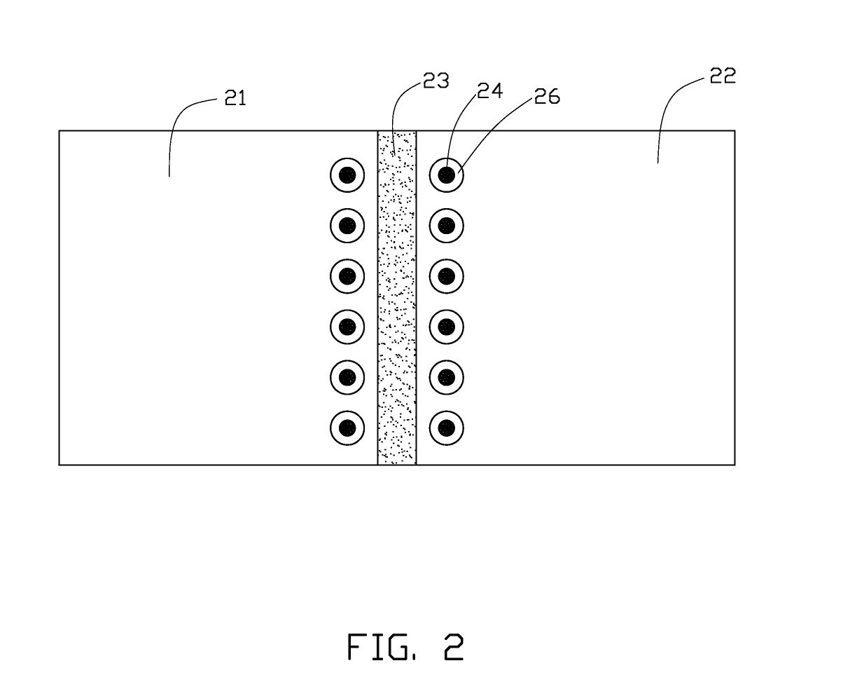

Referring to FIGS. 1 and 2, a printed circuit board (PCB) in accordance with a preferred embodiment of the present invention includes a ground plane 10, a power plane 20, and a plurality of vias 24. The power plane 20 includes two power modules 21, 22 for respectively providing power for two electronic components (not shown), and a strip 23 which is made of insulating mediums for insulating the power module 21 from the power module 22. The ground plane 10 is insulated from the power plane 20 by fiberglass material (not shown). The insulating mediums are made up of fiberglass. The plurality of vias 24 is connected between the power plane 10 and the ground plane 20, and is close to the strip 23. Each via 24 is insulated from the power modules 21 and 22 by an annular insulating medium 26. The vias 24 in the power module 21 are arranged in a line parallel and close to the strip 23, and the vias 24 in the power module 22 are arranged in a line parallel and close to the strip 23. The vias 24 in the power module 21 and the power module 22 are symmetrically aligned in the preferred embodiment, but may be aligned offset from each other in another embodiment. The vias 24 in each of the power modules 21 and 22 can be arranged in more than one line.

Each power module 21 and 22, and the vias 24 form an equivalent coupling capacitance therebetween. When drivers in one of the electronic components simultaneously switch from one state to another, simultaneous switching noise (SSN) transmitted from the power module 21 to the power module 22, or the SSN transmitted from the power module 22 to the power module 21 can be conducted to the ground plane 10 via the equivalent coupling capacitance. Therefore, the SSN in the PCB is suppressed.

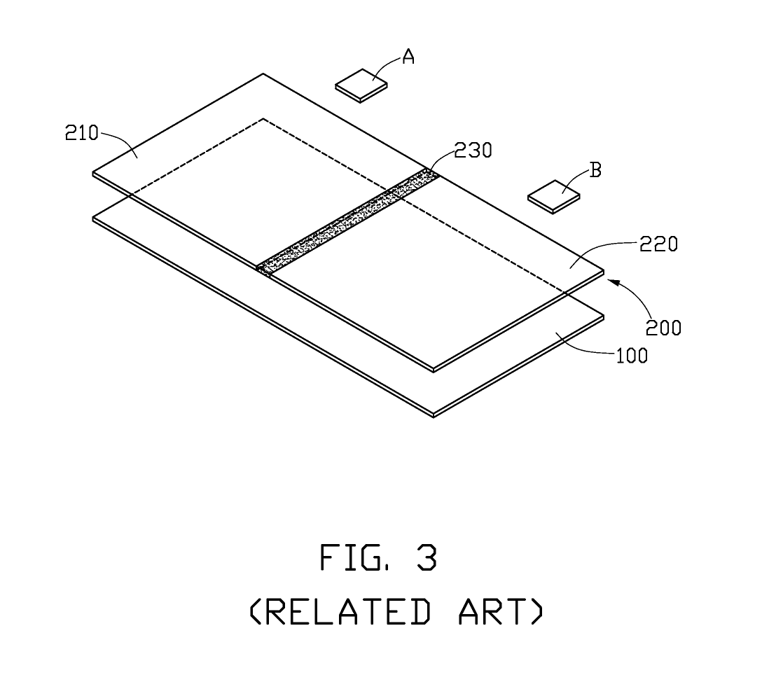

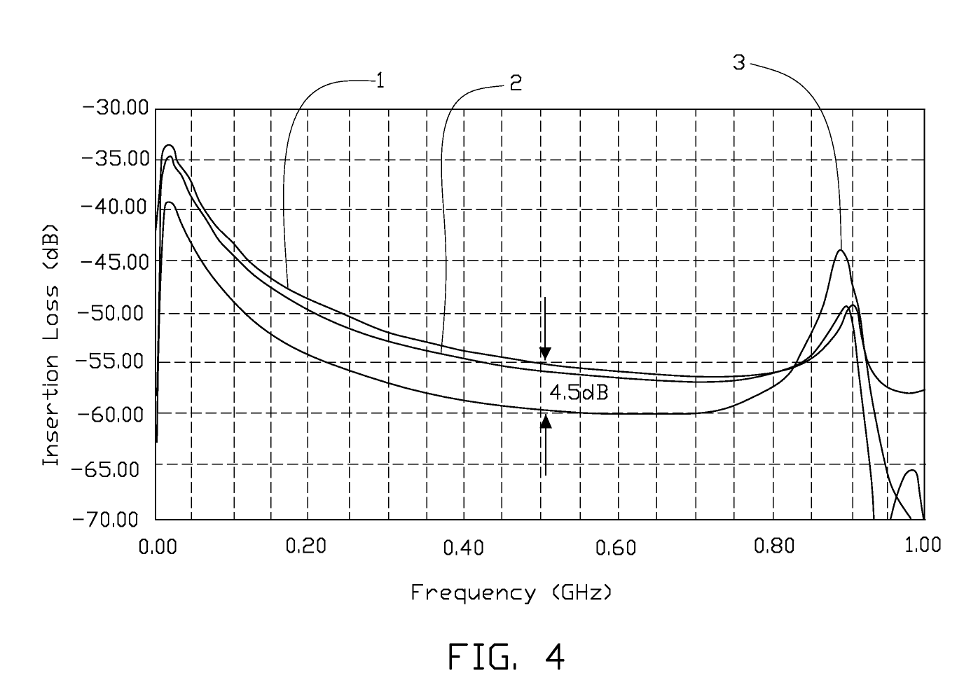

FIG. 4 shows a graph comparing insertion loss versus frequency in the PCBs of FIGS. 1 and 3. Curves c2, c1 are respective insertion loss versus frequency curves of the PCBs of FIGS. 1 and 3, and curve C2 is insertion loss versus frequency of a PCB which has 52 vias 24 defined therein. The curves c2 and c3 show the insertion loss of the PCBs of the present embodiment are less than the insertion loss of the PCB of FIG. 3 when the frequency is less than 0.9 GHz. Less insertion loss indicates a better effect of blocking the SSN. The number of the vias 24 can be altered, the more vias 24, the better effect of blocking the SSN.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A printed circuit board comprising:
a power plane comprising two power modules, and a strip made of insulating medium disposed between the two power modules for insulating the two power modules from each other;
a ground plane insulated from the power plane; and
a plurality of vias electrically connecting the power plane with the ground plane, and being close to the strip, wherein each via is insulated from the power modules by an annular insulating medium.

2. The printed circuit board as claimed in claim 1, where the plurality of vias is layout symmetrically about the strip.

3. The printed circuit board as claimed in claim 1, wherein the insulating medium is made up of fiberglass material.

4. A printed circuit board comprising:
a power plane comprising a first power module, a second power module, and a strip for insulating the first power module from the second power module;
a ground portion insulated from the power plane; and
a plurality of first vias connecting the first power module with the ground portion;
a plurality of second vias connecting the second power module with the ground portion, the first and second vias disposed at opposite sides of the strip and adjacent to the strip such that the power modules and the corresponding vias form equivalent coupling capacitances for conducting simultaneous switching noise (SSN) transmitted between the two power modules to the ground plane, wherein each first via and second via is insulated from the first and second power modules by an insulating medium.

5. The printed circuit board as claimed in claim 4, wherein the insulating medium is made up of fiberglass material.

6. The printed circuit board as claimed in claim 4, wherein the first vias are disposed in a line parallel to the strip, and the second vias are disposed in another line parallel to the strip.
